(19) United States
(12) Patent Application Publication
(10) Pub. No.: US 2008/0252305 A1
(43) Pub. Date: Oct. 16, 2008

(54) Device for analysing the composition of the contents of a receptacle including an analysis receptacle

(76) Inventor: Alessandro M. Manneschi, Arezzo (IT)

Correspondence Address: FOLEY AND LARDNER LLP;SUITE 500, 3000 K STREET NW, WASHINGTON, DC, 20007, US

(21) Appl. No.: 12/081,227

(22) Filed: Apr. 11, 2008

(30) Foreign Application Priority Data
Apr. 12, 2007 (FR) 0754439

(51) Int. Cl. G01R 27/02

(52) U.S. Cl. 324/693

(57) ABSTRACT

The invention relates a device for analysing the composition of the contents of a receptacle, including:
transmission/reception means (40′) of an electromagnetic field at least several frequencies lying in a given frequency range,
an identical receptacle (R′) for each analysis, intended to receive the content to be analysed,
support means (22′) for the receptacle (R′), adapted to ensure constant relative positioning between the transmission/reception means (40′) and the receptacle (R′),
means (50) adapted to measure the complex impedance of the transmission/reception means (40′) influenced by the load composed of the receptacle (R′) and its contents, representing the complex dielectric characteristics of the receptacle (R′) and of its contents,
means (50) adapted to supply information relating to the nature of the contents of the said receptacle (R′) as a function of the measured complex impedance.

The present invention relates the field of analysing the composition of the contents of receptacles such as bottles.

The present invention may find many applications. It may be applied in particular to the monitoring of production in bottling plants in order to prevent any criminal alteration of the contents of receptacles supplied later to the general public. The invention may also be applied to the checking of luggage transported by passengers, and in particular of the hand luggage retained by passengers in airports.

### PRIOR ART

The well-known devices for examination by x-ray techniques cannot be used to determine the contents of bottles or equivalent receptacles. Such devices for examination purposes actually only allow the classification into two categories, namely organic materials and inorganic materials. They cannot be used to distinguish between two organic materials.

We are also familiar, from document US 2002/0050828, with a device for the dielectric measurement of a material operating in the field of microwaves. The device includes a monostatic antenna, meaning that the antenna is common to the transmission/reception means of the device.

This device employs the resonance phenomenon of the monostatic antenna in order to perform the dielectric measurement. In fact, when a material is located close to the antenna, the latter changes the resonant frequency of the antenna. The device described in US 2002/0050828 is therefore based on measuring the complex impedance of the antenna, which is changed by the material located close to the latter.

This device has many drawbacks. In particular, the waves whose frequency is located in the field of microwaves have a very low penetration coefficient into the liquids. Moreover, in the case of US 2002/0050828, only a limited layer of the material to be analysed interacts with the antenna, and not all the volume of the material. As a consequence, the device described in US 2002/0050828 does not allow reliable measurement of the material to be analysed as a whole.

In order to overcome this drawback, a device for analysing the composition of the contents of a receptacle has been developed. This device is described in document EP 1 712 900 in particular.

This device includes transmission/reception means of an electromagnetic field at least several frequencies lying in a given frequency range, support means intended to receive a sealed receptacle whose contents must be analysed, adapted to ensure precise relative positioning between the transmission/reception means and the receptacle, means adapted to measure the complex impedance of the transmission/reception means influenced by the load composed of the receptacle and its contents, representing the complex dielectric characteristics of the receptacle and of its contents, and means adapted to supply information linked to the measured complex impedance and consequently to the nature of the contents of the said receptacle.

One advantage of this device is that it can be used to detect the contents of a receptacle with a high degree of reliability.

Nevertheless, this device does not allow the analysis of liquid contained in an unsealed receptacle such as a glass or a cup, due in particular to the shape of the support means.

In fact, in this case, the liquid contained in the receptacle spreads to the interior of the support means.

Likewise, this device does not allow the analysis of a metallic receptacle such as a tin can.

In fact, the electromagnetic field generated by the transmission/reception means do not penetrate to the interior of metal receptacles, so that analysing the contents of this type of metal receptacle is rendered impossible.

One objective of the invention is to propose a device that can be used to overcome at least one of the aforementioned drawbacks.

Another aim of the invention is to improve reliability when analysing the aforementioned device.

### SUMMARY OF THE INVENTION

To this end, a device is proposed for analysing the composition of the contents of a receptacle, including:
transmission/reception means of an electromagnetic field at least several frequencies lying in a given frequency range,
an identical receptacle for each analysis, intended to receive the content to be analysed,
support means for the receptacle, adapted to ensure constant relative positioning between the transmission/reception means and the receptacle,
means adapted to measure the complex impedance of the transmission/reception means influenced by the load composed of the receptacle and its contents, representing the complex dielectric characteristics of the receptacle and of its contents,
means adapted to supply information relating to the nature of the contents of the said receptacle as a function of the measured complex impedance.

In the context of the present invention, an “identical receptacle for each analysis” means a receptacle of a standardised type. Thus, the receptacle may change from an analysis to the next, especially in the event of damage to the analysis receptacle, but the characteristics (material, dimensions, shape, etc.) of the replacement receptacle remains identical to that of the original analysis receptacle.

Thus, the device of the invention allows measurement of the complex impedance of the contents of the receptacle, in contrast to the device described in document US 2002/0050828, which proposes measurement of the complex impedance of the monostatic antenna influenced by the material located nearby.

Moreover, the device of the invention uses a bistatic antenna, or indeed a multistatic antenna, according to the embodiments. This can be used to take account of all the contents of the receptacle since the electromagnetic field emitted by the transmission devices passes through all the contents of the receptacle before being received by the receiver devices.

The transmission/reception means are preferably adapted to generate an electromagnetic field at least several frequencies lying in a given frequency range, where the said frequencies are not resonant frequencies. In fact, in the case of the present invention, the resonant frequency produces parasitics.

The presence of a receptacle of constant shape and dimensions can be used to render the electromagnetic response of the transmission/reception means independent of the receptacle. Thus, this response depends only on the liquid contained in the receptacle, which can be used to maximise the selectivity of the analysis device.

Preferred but not limiting aspects of the device of the invention are as follows:
the receptacle is intended to receive a constant volume of liquid;
the dimensions of the receptacle are designed so as to contain a constant volume of liquid of between 2 and 10 centilitres;
the material constituting the walls of the receptacle is polypropylene, polyethylene or teflon;
the dimensions of the receptacle are designed so as to mate closely with the walls of the support means;

thus, the shape of the receptacle is therefore complementary to the shape of the support means in which the transmission/reception means, used for measuring the complex impedance of the contents of the analysis receptacle, are located. This can be used to improve the precision of the measurement and therefore of the information relating to the nature of the contents of the receptacle;
the support means are designed so that, in use, the support means surround the walls of the receptacle;
the transmission/reception means include at least one antenna;
the support means and the transmission/reception means are arranged so that, in use, the receptacle is located at the centre of the antennae;

the fact that the receptacle and its contents to be analysed are located at the centre of the antennae allows the analysis of all the volume of the contents of the receptacle.
the device also includes:
second transmission/reception means of an electromagnetic field at least several frequencies lying in a given frequency range,
second support means for another receptacle whose contents must be analysed, adapted to ensure precise relative positioning between the second transmission/reception means and the other receptacle;
the means adapted to measure the complex impedance of the transmission/reception means and the means adapted to supply information relating to the nature of the contents of the receptacle are also adapted respectively:
to measure the complex impedance of the second transmission/reception means influenced by the load composed of the other receptacle and its contents, representing the complex dielectric characteristics of the other receptacle and of its contents, and
to supply information relating to the nature of the contents of the other receptacle as a function of the measured complex impedance,

wherein the device includes switching means to switch the said means from analysing the contents of the receptacle to analysing the contents of the other receptacle.

### PRESENTATION OF THE FIGURES

Other characteristics, aims and advantages of the present invention will appear on reading the detailed description that follows, and with reference to the appended drawings, which are provided by way of non-limiting examples and in which:

FIG. 1 represents a schematic view in perspective of an analysis device according to a first embodiment of the present invention,

FIG. 2 represents a schematic view in the form of functional blocks of the essential elements making up this device,

FIG. 3 represents the real part and the imaginary part of the measured complex impedance in the case of a load composed of water, over a wide frequency range,

FIGS. 4 and 5 represent two schematic views in perspective of variants of the device represented in FIG. 1,

FIGS. 6, 7, 8 and 9 represent four embodiment variants of electromagnetic transmission/reception sensors according to the present invention, and

FIGS. 10a, 10b and 10c represent a fifth embodiment variant, while FIGS. 11a and 11b represent a sixth embodiment variant, of electromagnetic transmission/reception sensors according to the present invention,

FIGS. 12a and 12b, and 13a and 13b represent embodiment variants of the invention used for the analysis of receptacles with variable volumes,

FIG. 14 illustrates an embodiment of the display and entry means of the device.

### DESCRIPTION OF THE INVENTION

The present invention is essentially based on the following approach.

The dielectric materials present four basic polarisations: electronic, ionic, dipole and migrational.

Each type of polarisation is characterised by a set-up time, called the rise time. If the electromagnetic excitation field has a pulse that is greater than the inverse of the rise time, then polarisation cannot occur. As a consequence, the polarisation is present only at frequencies below the cut-off frequencies and is absent at the higher frequencies. In the transition zone, one is witnessing an energy-loss phenomenon in the dielectric due to rotation of the out-of-phase molecules in relation to the excitation field.

The rise times for electronic polarisation are 10⁻¹⁴ to 10⁻¹⁵ seconds, which is in the optical field. Such a frequency range is difficult to work with on the industrial scale, since the bottles to be examined may often be partially or completely opaque.

Ionic polarisation has rise times of between 10⁻¹³ and 10⁻¹⁴ seconds, which is very close to the electronic relaxation times. It is therefore also difficult to work with.

Dipole polarisation is characteristic of the polar dielectrics (like water for example).

Dipole polarisation, in contrast to the electronic and ionic polarisations, which have no inertia, persists for a certain time after the removal of the excitation signal. Dipole polarisation decays with an exponential law and a time constant, called the relaxation time, of between 10⁻⁶ and 10⁻¹¹ seconds, which is in the radio frequency field. The electromagnetic waves at these frequencies may pass through glass, plastic materials, and other dielectric materials. The Applicant has thus determined that electromagnetic waves may be used for examining the contents of bottles or equivalent receptacles.

Migrational polarisation is present in certain dielectrics, in particular in heterogeneous materials that contain impurities. In this case, the charges move very slowly, and the rise time may be several seconds, minutes, or sometimes even hours. As a consequence, this type of polarisation is measurable only at very low frequency.

Water, which is a polar liquid, and as a consequence all water-based liquids, have a relaxation time of the order of 10⁻¹¹ seconds at ambient temperature, corresponding to a frequency of about 16 GHz. Measurement of the complex dielectric constant at frequencies lower than the relaxation frequency shows a high real part and limited losses (distilled water) as illustrated by FIG. 3 attached.

The saturated hydrocarbons, CnH(2n+2), are non-polar molecules or with a very low electric dipole moment. As a consequence, they do not exhibit a dipole polarisation phenomenon, and the value of the real part of the dielectric constant is low (relative dielectric constant of the order of 2). The losses in the hydrocarbons are negligible up to very high frequencies. If a hydrocarbon molecule loses its symmetry, as in the case of the ethyl or methyl alcohol for example, one is witnessing the appearance of an electric dipole moment and, as a consequence, a constant that is greater than that obtained in the case of the hydrocarbons, and a resonance phenomenon at the dipolar relaxation frequency.

The physical phenomena described above have been known since the end of the 1930s (see for example the Peter Debye Nobel Lecture from 1936).

However, up to the present, they have not been used for the efficient analysis of the contents of receptacles.

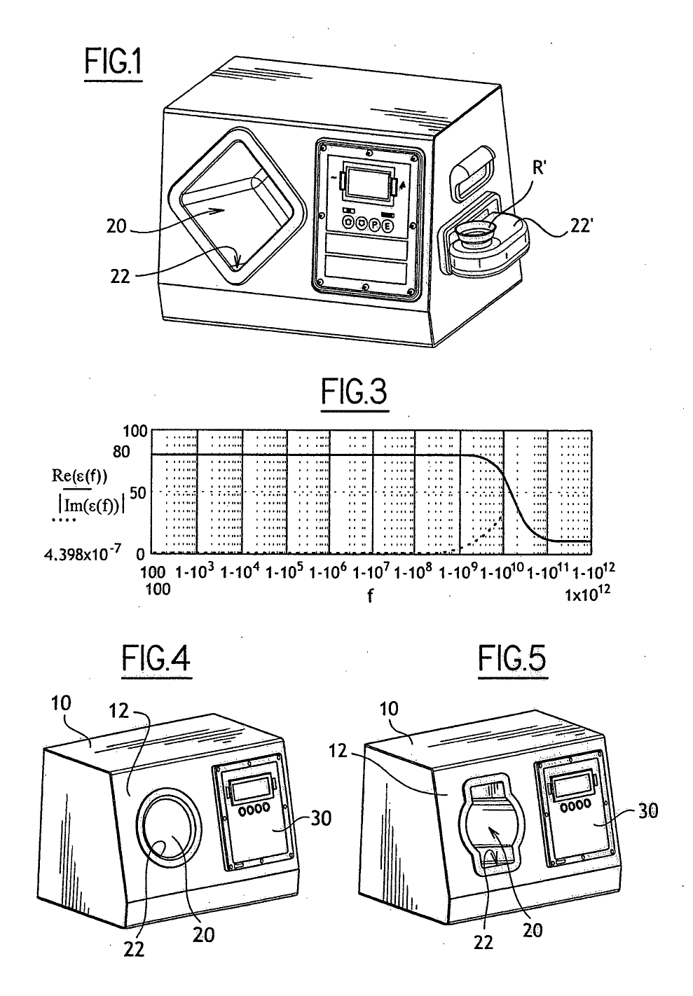

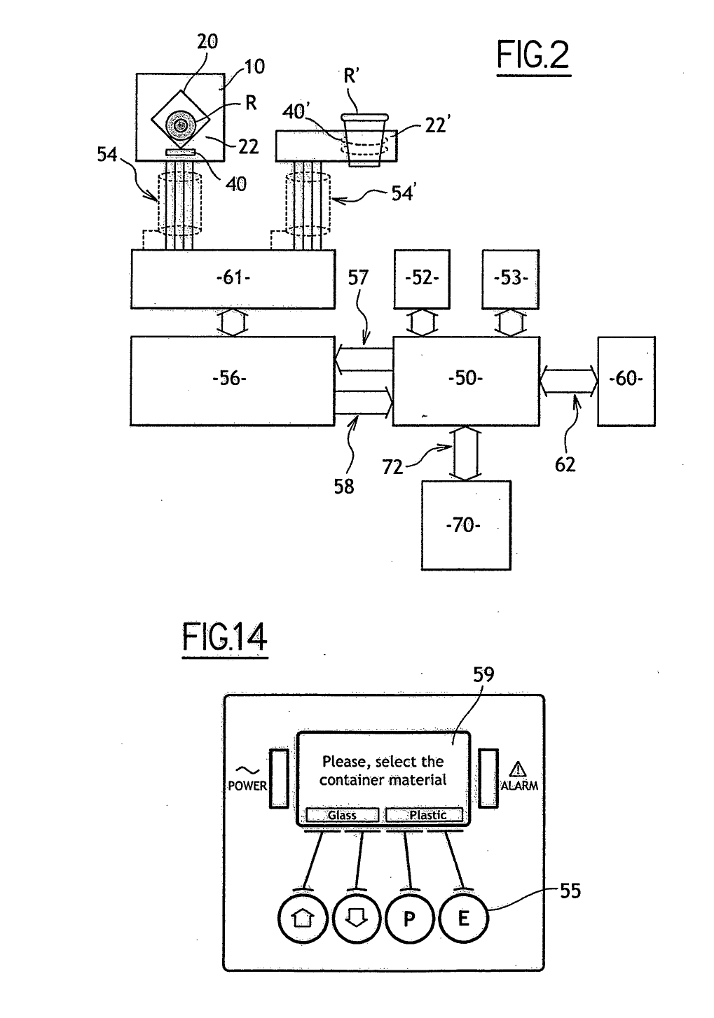

FIGS. 1 and 2 represent one embodiment of an analysis device according to the present invention.

The device for analysing the composition of the contents of a receptacle includes:
transmission/reception means 40′ of an electromagnetic field,
a receptacle R′ intended to receive the content to be analysed,
support means 22′ for the receptacle,
means 50 adapted to measure the complex impedance of the transmission/reception means, influenced by the load composed of the receptacle and its contents,
means adapted to supply information relating to the nature of the contents of the receptacle.

The transmission/reception means 40′ are used for the transmission and the reception of a magnetic field at least several frequencies lying in a given frequency range.

The transmission/reception means 40′ are preferably formed of one or more antennae, connected by means of a connection network 54′ of an electromagnetic measurement network 56 and bus 57, 58, to a generator 50, designed to transmit an electromagnetic wave.

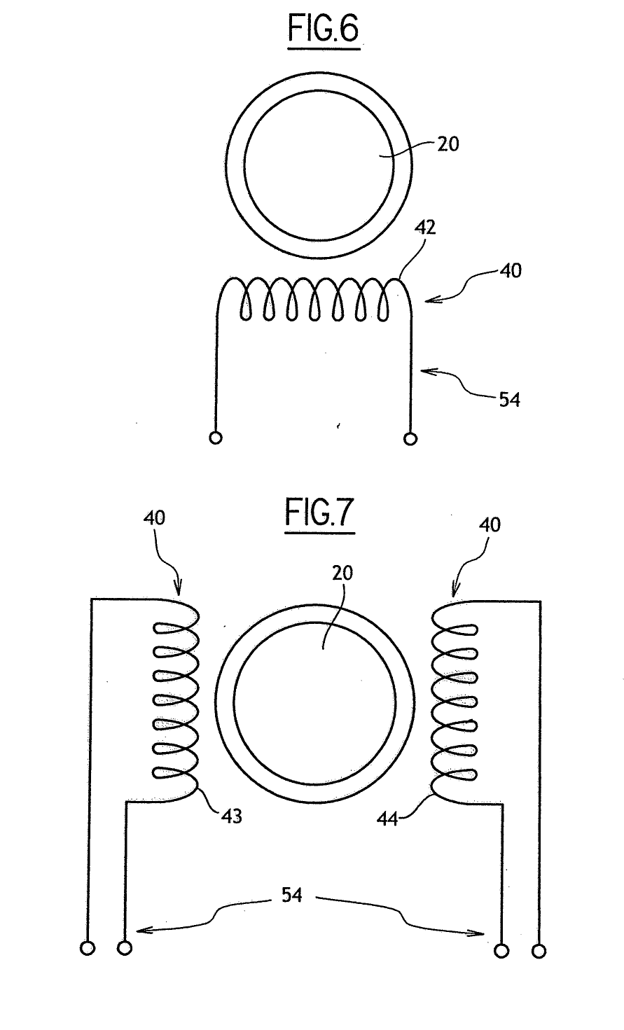

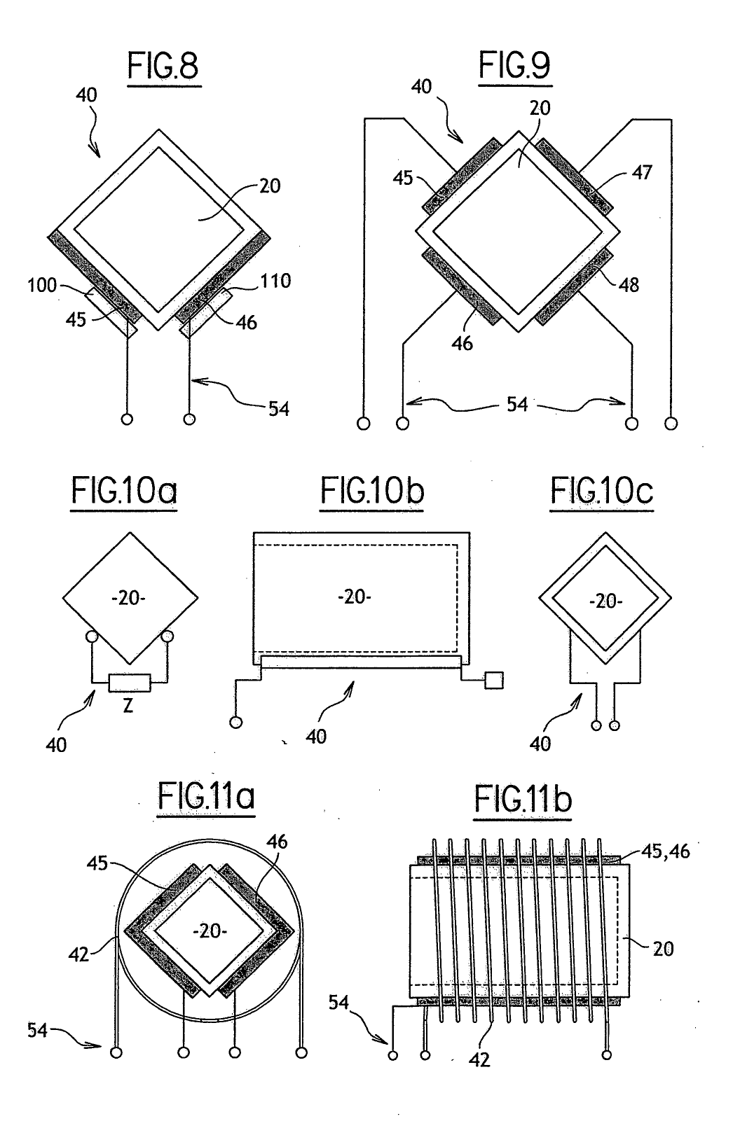

The transmission/reception means 40′ may advantageously be formed of:
a simple winding forming the transmitter and the receiver (such as the winding 42 illustrated in FIG. 6),
two windings respectively, and alternately if necessary, forming an transmitter and receiver (such as windings 43 and 44 illustrated in FIG. 7),
two armatures with a capacity surrounding a housing for the support means 22 intended to receive the receptacle (such as armatures 45, 46 illustrated in FIGS. 8, 12a, 12b, 13a and 13b),
four armatures with two capacities surrounding the housing for the support means 22, respectively, and alternately if necessary, forming an transmitter and receiver (such as armatures 45, 46, 47 and 48 illustrated in FIG. 9),
two-wire lines or slot waveguides (such as the transmission lines illustrated in FIGS. 10a, 10b and 10c),
an inductive transducer 42 and a capacitive transducer (such as transducers 42, 45 and 46 illustrated in FIGS. 11a and 11b).

In all cases, the dimensions of the transmission/reception means 40 are matched to the dimensions of the support means 22.

Typically, the generator 50 is adapted to cover the frequency range from a few Hz, for example 5 Hz up to a few GHz, 20 or 50 GHz for example. The generator 50 is operated either manually by an operator when the latter inserts a receptacle R′ into the support means 22′, or automatically under the influence of a sensor 52 designed to detect the presence of a receptacle R′ in the support means 22′.

Means 50 are also designed to measure the complex impedance of the transmission means 40′ influenced by the load composed of the receptacle R and its contents, representing the complex dielectric characteristics of this receptacle R and of its contents. More precisely, means 50 are designed to measure this complex impedance at several frequencies sampled in the aforementioned excitation range from a few Hz to several GHz. Typically, means 50 thus operate on a number of frequencies between 10 and 50, advantageously on some thirty or so frequencies.

Moreover, means 50 are adapted to supply information linked to the measured complex impedance, and to the nature of the contents of the receptacle detected as a consequence.

These means 50 are preferably adapted to compare the complex impedance thus measured with predetermined reference values for the same frequency range, and to generate an alarm when the measured complex impedance differs from the reference values.

FIG. 2 shows a memory 60 coupled to the analysis means 50 by a communication bus 62, and in which the predetermined reference values over the working frequency range may be stored. FIG. 2 also shows, under reference 70, alarm means with are preferably present on the control desk 30, connected to means 50 via a communication bus 72 and adapted to generate an audio or visual alarm when the measured complex impedance differs from the reference values.

Also, in a variant, means 70 may be adapted to directly indicate the nature of the contents of the receptacle R′ or at least the family of this content, in place of or in addition to the aforementioned alarm means.

The receptacle R′ is intended to receive the content to be analysed. An identical receptacle for each analysis may be used to ensure constant relative positioning between the transmission/reception means and the receptacle R′. Ensuring constant relative positioning of the receptacle R′ enables us to remove one of the variables in the analysis, namely the variability in the positioning of the receptacle containing the liquid to be analysed in relation to the transmission/reception means.

The receptacle R′ is preferably intended to receive a constant volume of liquid. The dimensions of the receptacle are designed, for example, to receive a constant volume of liquid of between 2 and 10 centilitres.

Moreover, the thickness of the walls of the receptacle R′ may be constant. The material constituting the walls of the receptacle R′ is preferably polypropylene or polyethylene. The material constituting the receptacle may advantageously be teflon, for reasons of chemical resistance. In fact, the teflon presents good resistance to most chemical substances, and in particular acids, alkalis, alcohols, ketones and hydrocarbons. This can be used to avoid damaging the receptacle and any splashes onto the user, on the assumption that the tested liquid would be of the type described previously.

Using identical receptacles for all the analyses can be used to increase the reliability of the device by reducing the acceptance window of the measured complex impedance.

Without constancy of the receptacle used for the analysis, the acceptance window must be sufficiently wide to take account of the variability in physical factors in relation to the different types of receptacle liable to be analysed.

These physical factors are as follows for example:
the material constituting the walls of the receptacle,
the thickness of the walls of the receptacle,
the capacity (or volume) of the receptacle.

The support means 22′ are specially adapted to support the receptacle R′.

The dimensions of the support means 22′ are preferably designed so as to mate closely with the walls of the receptacle R′.

Moreover, the support means 22′ are designed so that, in use, the support means 22′ surround the walls of the receptacle R′.

The support means can be designed to receive the wound antenna or antennae constituting the transmission/reception means so that, in use, the receptacle R′ is located at the centre of the wound antenna or antennae.

Advantageously, and as illustrated in FIG. 1, the device described previously may be used in combination with the device described in document EP 1 712 900 and described below. It will be seen that the analysis method used in these two devices is the same.

The device then includes:
second transmission/reception means 40,
second support means 22 for a second receptacle R whose contents must be analysed.

In this case, the transmission/reception means 40′ of the first receptacle R′ and the second transmission/reception means 40 of the second receptacle R are connected to the analysis means 50 by switching means 61, so as to switch the said analysis means 50 from analysing the contents of the first receptacle R′ to analysing the contents of the second receptacle R. This can be used to avoid duplication of the electronic of the device and therefore to propose a less expensive device.

The general geometry of the housing represented in FIG. 1 may be the subject of many embodiment variants and will therefore not be described in the detail in what follows.

This housing preferably includes a metal casing 10 to form a screen around an electromagnetic sensor in relation to the external environment.

This casing preferably forms a cavity 20 whose lower part 22 has a concave shape facing upwards. The lower part 22, formed by the second support means, is designed to receive a second receptacle R to be analysed, and to guarantee precise positioning of the latter in relation to second means for the transmission/reception of an electromagnetic field 40.

More precisely still, in the context of the present invention, the aforementioned cavity 20 is formed of a channel of constant cross section, whose axes are inclined downwards away from the open front face 12 by which a second receptacle R is inserted.

The rear face of this cavity or channel 20 is preferably closed in order to prevent the second receptacle R analysed from slipping on the bottom 22.

The cross section of the channel 20 may be the subject of many variants. FIG. 5 shows a first variant, according to which the channel 20 has a cross section in the shape of keyhole, with a central cylindrical part extended by two diametrically opposite excrescences of generally rectangular shape. The advantages of the different variants of cross section will be explained in what follows.

FIG. 4 shows an embodiment variant in which the channel 20 has a circular cross section. FIG. 1 attached shows another embodiment variant in which the channel 20 has a square cross or even rectangular section, whose diagonals are respectively vertical and horizontal so that one edge coincides with the lowest point of the channel 20.

As can be seen in FIGS. 1, 4 and 5 attached, the housing 10 also preferably includes a control desk 30 equipped with an entry and/or programming keypad, a display unit, and means for signalling (light and/or sound) the presence of the network and of alarms. In this regard, the invention is naturally not limited to the particular embodiments represented in the attached figures.

The cavity 20 is preferably covered by a protective plastic coating.

As illustrated in FIG. 2, in which reference R refers to a receptacle to be analysed, and in which the bottom 22 of the cavity 20 can be seen, the electromagnetic sensor or sensors intended to measure the complex dielectric characteristics of the second receptacle R and of its contents are preferably placed around the cavity 20.

These second transmission/reception means of the electromagnetic field, preferably formed of one or more transducers (antennae) 40 connected, by means of a second connection network 54, from the electromagnetic measurement network 56 and bus 57, 58 to the generator 50, designed to emit an electromagnetic wave. Typically the analysis means 50 are adapted to cover the frequency range from a few Hz, 5 Hz for example, to a few GHz, 20 or 50 GHz for example. The analysis means 50 are operated either manually by an operator, when the latter inserts a second receptacle R in the channel 20, or automatically under the influence of a sensor 52 designed to detect the presence of a second receptacle R in the channel 20.

Means 50 are also designed to measure the complex impedance of the second transmission means 40 influenced by the load composed of the second receptacle R and its contents, representing the complex dielectric characteristics of this second receptacle R and of its contents. More precisely, means 50 are designed to measure this complex impedance at several frequencies sampled in the aforementioned excitation range of a few Hz to several GHz. Typically, means 50 thus operate on a number of frequencies, between 10 and 50, and advantageously on some thirty or so frequencies.

Moreover, means 50 are adapted to supply information linked to the measured complex impedance and to the nature of the contents of the second receptacle detected as a consequence.

These means 50 are preferably adapted to compare the complex impedance thus measured with second predetermined reference values for the same frequency range, and to generate an alarm when the measured complex impedance differs from the reference values.

It will be seen that the predetermined reference values for the first and second receptacles may be different.

In fact, the first predetermined reference values are determined in relation to the first receptacle R′ of constant shape, dimensions and material, while the second predetermined values relate to any type of second receptacle.

The second predetermined values may be stored in the memory 60.

In a variant, the reference values may be calculated by means 50, and not contained in a memory 60.

The second transmission/reception means 40 of the electromagnetic field may be the subject of many embodiments.

FIG. 6 illustrates a first embodiment in which these second means 40 are formed from a simple winding 42 forming the transmitter and receiver, connected by a 2-wire network 54 to the electromagnetic measurement network 56.

FIG. 7 illustrates a second embodiment in which the second means 40 are formed from two windings 43, 44 respectively, and alternately if necessary, forming the transmitter and receiver, connected by a 4-wire network 54 to the electromagnetic measurement network 56.

FIG. 8 illustrates a third embodiment in which the second means 40 are formed from two armatures 45, 46 with a capacity, surrounding the cavity 20 intended to receive the receptacle R and connected by a 2-wire network 54 to the electromagnetic measurement network 56.

FIG. 9 illustrates a variant of FIG. 8, in which the second means 40 include two capacitances composed of four armatures 45, 46, 47, 48, connected by a 4-wire network 54 to the electromagnetic measurement network 56 and respectively forming, and alternately if necessary, the emitter and receiver.

FIGS. 10a, 10b, 10c represent another embodiment variant in which the second means 40 are formed from transmission lines. Typically, these transmission lines operate in the field of microwaves. They may be formed by two-wire lines or slot waveguides.

Moreover, in the context of the present invention, as illustrated in FIGS. 11a and 11b, it is possible to use sensors that simultaneously implement an inductive transducer 42 and a capacitive transducer 45, 46. This arrangement can be used to determine whether the increase in the real part of the complex dielectric constant is due to a metal armature inside the second receptacle R and not to one or more liquids with particular properties. This arrangement thus allows one to detect the presence of metal screens that are liable to form a screen that disrupts the measurement. The inductive sensor 42 powered by an alternating-current power source will, in this case, produce eddy currents in the metal parts. These currents will be measured by the processing device. The comparison of the signals coming from the electric field transducer 45, 46 and from the magnetic field transducer 42 results in satisfactory detection. In the case where the second receptacle R includes metal screens, it will be possible to place a sample of the contents of the second receptacle R in the first receptacle R′ in order to perform liquid analysis.

Naturally, the number of second means making up the transmitters and/or receivers is not limited in any way, and may be greater than those illustrated in the attached figures.

On reading the foregoing detailed description, those skilled in the art will understand that the present invention thus proposes an electromagnetic sensor for the scanning of high frequencies that can be used to measure the dielectric characteristics of a receptacle and of its contents.

Once a second receptacle R to be analysed is positioned in the cavity 20, the generator 50 is activated, either manually or automatically, and the complex impedance of the network formed by the second transmission/reception circuit 40 influenced by the second receptacle R and its contents is measured.

The impedance measured depends on the transmission/reception circuit and the load, represented by the second receptacle examined (a bottle for example). This complex impedance is composed of a real part, linked to the losses (conductivity) in the objet R analysed, and an imaginary part, linked to the dielectric characteristics.

Measurement of the impedance is effected at different frequencies in the given range.

All the water-based consumable liquids, such as non-alcoholic drinks, wine and liquors are easily identifiable by their dielectric polar characteristics, with a high dielectric constant and losses located between a minimum and a predetermined value. A value that is different from that which is typical of consumable liquids will therefore be detected and will give rise to an audio or visual alarm, in addition, where necessary, to messages on the display unit, or indeed, according to the chosen variant, with a direct indication of the nature of the contents detected.

As described previously, the cross section of the channel 20 may be the subject of many variants. For example, the cross section may be in the shape of a keyhole, as illustrated in FIG. 5, and the cross section may also be of circular shape as illustrated in FIG. 4, or of square or even rectangular shape (with vertical and horizontal diagonals) as illustrated in FIG. 1.

For certain geometries of the cross section of the channel, the measured complex impedance may vary as a function of the volume of the second receptacle in which a given analysed liquid is contained.

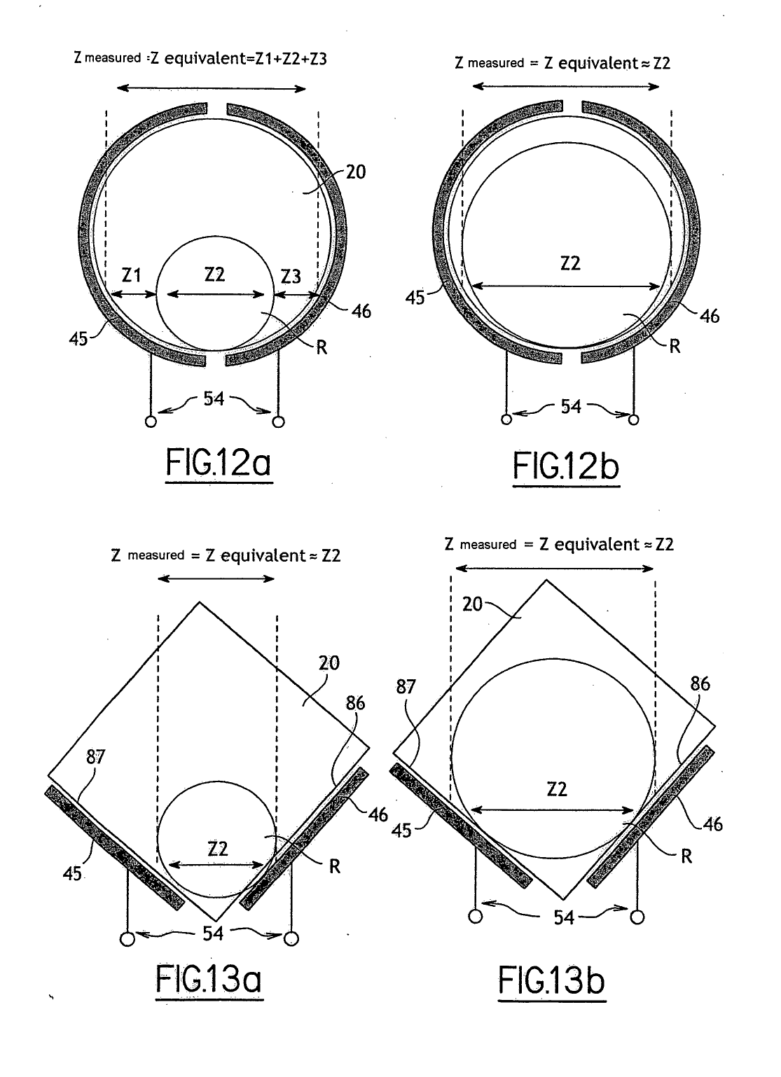

Thus, in the case of a channel 20 whose cross section is of circular shape as illustrated in FIGS. 12a and 12b, the measured complex impedance Zmeasured for a second 50-centilitre receptacle R containing water (FIG. 12a) will be different from the measured complex impedance Zmeasured for a second 2-litre receptacle R containing water (FIG. 12b).

This is due to the fact that the measured complex impedance Zmeasured corresponds to the equivalent complex impedance Zequivalent of all the dipoles located between the armatures 45, 46 of the second transmission/reception means of an electromagnetic field.

FIGS. 12a and 12b show a device including a channel 20 with a cross section whose shape is circular and specially adapted to measure the complex impedance of the contents of a 2-litre cylindrical bottle, meaning a channel 20 in which the diameter of the cross section is slightly greater than the diameter of a 2-litre cylindrical bottle.

As illustrated in FIG. 12a, when one uses this device with a second receptacle R of 50 centilitres, located in the channel 20 so that the longitudinal axis of the receptacle R is substantially horizontal, then the measured complex impedance Zmeasured is equal to the sum of the complex impedance of the water Z2 contained in the second receptacle R and the complex impedances Z1, Z3 of the air located between the walls of the second receptacle R and the armatures 45, 46.

The complex impedances Z1 and Z3 of the air located between the walls of the second receptacle R and the armatures 45, 46 are considered to be parasitic impedances which need to be minimised in order that the measured complex impedance should be substantially equal to the complex impedance of the liquid contained in the second receptacle to be analysed.

As illustrated in FIG. 12b, when one uses this device with a second 2-litre receptacle, for which the cross section is specially adapted, the measured complex impedance Zmeasured is substantially equal to the complex impedance of the water Z2 contained in the second receptacle R.

In fact, with a 2-litre receptacle for which the cross section is specially adapted, the parasitic impedances Z1, Z3 become negligible due to the fact that the distances between the walls of the second receptacle R and the armatures 45, 46 are small.

The square (or rectangular) and keyhole geometries of the cross section have the advantage of rendering measurement of the complex impedance independent of the volume of the second receptacle in which the liquid to be analysed is contained.

In fact, these geometries enable us to limit the distance between the walls of the second receptacle R and the armatures 45, 46 of the second transmission/reception means of an electromagnetic field, regardless of the volume of the second receptacle R.

FIGS. 13a and 13b show a device according to the present invention including a channel 20 whose cross section is of square shape, with diagonals that are respectively vertical and horizontal, so that one edge coincides with the lowest point of the channel 20.

In the case of a second receptacle R of cylindrical shape located in the channel 20 so that the longitudinal axis of the second receptacle R is horizontal, the second receptacle R will tend to come into contact with the partitions 86, 87 of the channel 20 due to gravity, as illustrated in FIGS. 13a and 13b.

Thus, the distance between the walls of the second receptacle and the armatures 45, 46 (which are very close to the partitions 86, 87 of the channel 20 is virtually zero, regardless of the diameter of the second receptacle containing the liquid to be analysed, so that the parasitic impedances Z1, Z3 of the air located between the walls of the second receptacle R and the armatures are negligible. The impedance measured Zmeasured is substantially equal to the complex impedance of the liquid contained in the second receptacle R, regardless of the volume of the second receptacle R used.

Just as for a channel whose cross section is square, a geometry with a cross section in the shape of a keyhole can be used to minimise the distance between the walls of the second receptacle containing the liquid to be analysed and the armatures of the device, regardless of the volume of the second receptacle R used, so that measurement of the complex impedance is independent of the volume of the second receptacle in which the liquid to be analysed is contained. Thus, in the case of a second cylindrical receptacle of 50 cl, the latter is positioned between the lower excrescences of the cross section in the shape of a keyhole (the distance between these excrescences may be made slightly greater than the diameter of a cylindrical bottle of 50 centilitres of the standard type). In the case of a second 2-litre receptacle, the latter is positioned at the central cylindrical part of the keyhole-shaped channel.

Thus, the channel 20 of the device preferably forms an upward-facing concave shape 22. Even more preferably, the convergence of the partitions 86, 87 of the channel 20 is determined so that not only does the distance between the lowest point of the channel 20 and the centre of gravity of the second receptacle R increase as a function of the volume of the second receptacle R, but also the point of contact of the second receptacle R with the walls of the channel 20 rises, and the height of the base of the second receptacle, in relation to the lowest point of the channel 20, also increases as a function of the volume of the second receptacle R. More preferably again, the upward-facing concave shape 22 is obtained by means of two rectilinear sections so as to minimise the effect of the parasitic impedances Z1, Z3 of the air located between the walls of the second receptacle R and the partitions 86, 87 of the channel 20.

The device described previously can be used to create non-destructive investigation resources to determine the composition of the contents of a receptacle.

In order to improve the reliability of the analysis device, it is proposed to incorporate into this device means 53, 55 used to obtain additional physical data relating to a characteristic of the receptacle analysed.

In a variant of the invention, the means used to obtain additional physical data include means to measure the mass of the second receptacle R analysed.

In fact, when the capacity of the second receptacle analysed is low (i.e. less than 200 ml), the device described previously tends to underestimate the complex impedance of the liquid contained in the receptacle analysed, which may lead to the emission of a false alarm.

More precisely, the complex impedance per unit of volume of a liquid measured in a second receptacle with a capacity of 100 ml for example, will be less than the complex impedance of the same liquid measured in a second receptacle with a capacity of 2 litres.

This also applies when a second square-shaped receptacle is located in a channel of square cross section. More precisely, the measured complex impedance of a liquid contained in a second 1-litre receptacle of square section will be greater than the measured complex impedance of the same liquid contained in a second cylindrical receptacle.

This is due to the fact that in both cases, the walls of the second receptacle (of square section, or of small capacity) mates closely with the walls of the channel (or at least more closely than a cylindrical receptacle with a capacity greater than 200 ml).

In order to increase the reliability of the device described previously, it is therefore proposed to obtain, for the analysis means 50, another item of data in addition to the measured complex impedance.

This additional data item is the mass of the second receptacle, and preferably of the second receptacle with its contents.

To measure the mass of the second receptacle and of the liquid that it contains, the device includes a gravity-measuring sensor 53.

The gravity-measuring sensor 53 is preferably built into the channel 20.

More precisely, the gravity-measuring sensor 53 is located under the lower part (or bottom 22) of the channel 20. This can be used to limit the size of the device.

The device thus works as follows.

The tare of the device is measured periodically. More precisely, when no receptacle is inserted into the channel 20, the gravity-measuring sensor 53 measures the mass of the lower part 22 of the channel 20. This measured tare is sent to means 50.

The presence of a receptacle in the channel 20 is detected:
either by the sensor 52,
or by means 50.

In the case where the presence of a receptacle is detected by means 50, this detection occurs as follows. The user places a receptacle onto the lower part 22 of the channel 20. The complex impedance of the transmission/reception means is influenced by the load composed of the receptacle R and its contents. The analysis means 50 detect this change of complex impedance, and emit a signal indicating the presence of a receptacle to be analysed, to interrupt periodic updating of the tare of the device.

The gravity-measuring sensor 53 measures the mass of the receptacle R and its contents, and sends a signal representing the measured mass to the analysis means 50.

The analysis means 50 associate the measured mass with the measured complex impedance for the receptacle R analysed.

More precisely, the measured mass is used to correct the amplitude of the measured complex impedance.

The complex impedance thus corrected is then compared to reference values, to determine the nature of the liquid contained in the receptacle R.

In another variant of the invention, the means used to obtain additional physical data include the means of entry 55 illustrated in FIGS. 2 and 14.

The entry means 55 can be used to enter additional data relating to the receptacle analysed.

By means of these additional data, the selectivity of the device may be increased.

In fact, the possession of additional data allows us to reduce the acceptance window onto the measured complex impedance. Without additional data, the acceptance window must be sufficiently wide to take account of the variability in physical factors, in relation to the different types of receptacle liable to be analysed, such as:
the material constituting the walls of the receptacle,
the thickness of the walls of the receptacle,
the capacity (or volume) of the receptacle.

The device may therefore include entry means 55 for the entry of additional data relating to the receptacle analysed.

In order to facilitate the use of the device, the analysis means 50 propose questions, displayed on the display means 59, with a list of possible responses.

By using these means 55, the user selects, the response that is most appropriate from the list of responses proposed, as a function of the receptacle analysed.

The additional data that the user must enter may be the capacity (i.e. volume) of the receptacle and/or the material constituting the walls of the receptacle and/or the thickness of the walls of the receptacle.

Advantageously, the analysis means 50 display questions relating to the receptacle analysed only when the entry of additional data relating to the receptacle analysed is necessary in order to determine the nature of the liquid contained in the receptacle analysed.

In this case, means 50 supply information relating to the nature of the contents of the receptacle as a function of the measured complex impedance and of the data entered by the user via the entry means 55.

For example, when the measured complex impedance differs from the reference values, the analysis means 50 tell the user (on the display means 59) to enter additional data via the entry means 55.

In yet another variant, the means used to obtain additional physical data include means for measuring firstly the mass, and secondly means of entry.

Naturally the present invention is not limited to the particular embodiments that have just been described, but extends to any variant that conforms to its spirit.

It will also be noted, in the context of the present invention, that the sensors 40 are preferably adapted to cover at least a substantial part of the receptacles, or even the totality of the latter. This guarantees a high level of security in the analysis, since this can be used to analyse the whole of the contents of the receptacles and not merely part of them.

When only one transducer is provided, the latter is simultaneously or successively the transmitter and the receiver.

When several transducers are provided, all combinations are possible, meaning that these transducers may be simultaneously or successively transmitters and/or receivers.

According to another advantageous characteristic, the analysis device according to the present invention also includes an assembly for the detection of ionising or radioactive radiation. This assembly is intended to detect the presence of any traces of radioactive substances in the receptacle analysed.

The detection assembly of ionising or radioactive radiation may be the subject of many embodiments. It may be formed from any structures known to those who are skilled in the art, and in particular any structure adapted to convert detected ionising radiation into a usable electrical signal. For example, and non-limitatively, it may be a detector of the Geiger type with a tube or chamber that contains a gas whose composition is chosen to generate an ionising discharge on detection of active radiation, and thereby an electrical pulse. It may also be a scintillation detector adapted to convert the detected energy into luminous scintillations which are then converted into an electrical signal by a network of photomultipliers. Many scintillators have been proposed for this purpose, based on sodium iodide, caesium iodide or indeed bismuth germanate for example.

The assembly for detection of ionising radiation is located in any appropriate position, and preferably in the immediate proximity of the walls of the cavity 20, on the outside of the latter. FIG. 8 shows, under the reference 100 and 110, a location that is optimal in principle for this assembly, under the cavity 20, against the two walls making up the lower dihedral of the cavity 20.

The detection assembly of ionising radiation 100, 110 is adapted to work in masked time, in parallel with the device for the measurement of complex impedance previously described. The detection assembly of ionising radiation 100, 110 is controlled and brought into service by any appropriate means for detecting the presence of a receptacle in the cavity. Preferably, but not limitatively, the detection assembly of ionising radiation is thus initiated by a signal taken from the chain for measurement of the complex impedance and representing the presence of such a receptacle in the channel 20.

We have previously described several embodiments of the second means 40 forming the transmitters/receivers of an electromagnetic field. In the context of the present invention, it is preferably to provide means that may be used to change the configuration of the second means forming the transmitters, and the means forming the receivers, in order to enhance the information available, on the volume of the receptacle analysed for example.

FIG. 9 shows in particular an embodiment variant according to which the second means 40 include four capacitive armatures 45, 46, 47, 48 located respectively on the outside of each of the four faces of a square section of the channel 20. In this context, it is preferable to provide a switch within the measuring network 56, in order to change the configuration of means 40 so that, in a first configuration, one of the two lower armatures 46 or 48 form an transmitter, while the other lower armature 48 or 46 forms a receiver, and a second configuration in which the two lower armatures 46, 48 form transmitters while the two upper armatures 45, 47 form receivers, or vice versa.

1-10. (canceled)

11. A device for analysing the composition of the contents of a receptacle, including:
transmission/reception means of an electromagnetic field at least several frequencies lying in a given frequency range,
an identical receptacle for each analysis, intended to receive the content to be analysed,
support means for the receptacle, adapted to ensure constant relative positioning between the transmission/reception means and the receptacle,
means adapted to measure the complex impedance of the transmission/reception means influenced by the load composed of the receptacle and its contents, representing the complex dielectric characteristics of the receptacle and of its contents,
means adapted to supply information relating to the nature of the contents of the said receptacle as a function of the measured complex impedance.

12. The device of claim 11, wherein the receptacle is intended to receive a constant volume of liquid.

13. The device of claim 11, wherein the dimensions of the receptacle are designed so as to contain a constant volume of liquid of between 2 and 10 centilitres.

14. The device of claim 11, wherein the material constituting the walls of the receptacle is polypropylene, polyethylene or teflon.

15. The device of claim 11, wherein the dimensions of the receptacle are designed so as to mate closely with the walls of the support means.

16. The device of claim 15, wherein the support means are designed so that, in use, the support means surround the walls of the receptacle.

17. The device of claim 11, wherein the transmission/reception means include at least one antenna.

18. The device of claims 16 and 17 taken together, wherein the support means and the transmission/reception means are arranged so that, in use, the receptacle is located at the centre of the antennae.

19. The device claim 11, further comprising:
second transmission/reception means of an electromagnetic field at least several frequencies lying in a given frequency range,
second means to support another receptacle whose contents must be analysed, adapted to ensure precise relative positioning between the second transmission/reception means and the other receptacle.

20. The device of claim 19, wherein:
the means adapted to measure the complex impedance of the transmission/reception means and
the means adapted to supply information relating to the nature of the contents of the receptacle
are further adapted respectively:
to measure the complex impedance of the second transmission/reception means influenced by the load composed of the other receptacle and its contents, representing the complex dielectric characteristics of the other receptacle and of its contents, and
to supply information relating to the nature of the contents of the other receptacle as a function of the measured complex impedance,
wherein the device includes switching means to switch the said means from analysing the contents of the receptacle to analysing the contents of the other receptacle.
